(19) United States
(12) Patent Application Publication
(10) Pub. No.: US 2008/0203408 A1
(43) Pub. Date: Aug. 28, 2008

(54) PROCESS FOR PRODUCING (Al, Ga)lnN CRYSTALS

(75) Inventors: Gunnar Leibiger, Freiberg (DE); Frank Habel, Freiberg (DE)

Correspondence Address: Connolly Bove Lodge & Hutz LLP, 1007 North Orange Street, P.O.Box 2207, Wilmington, DE, 19899-2207, US

(73) Assignee: Freiberger Compound Materials GmbH, Freiberg / Sachsen (DE)

(21) Appl. No.: 12/034,933

(22) Filed: Feb. 21, 2008

Related U.S. Application Data
(60) Provisional application No. 60/891,251, filed on Feb. 23, 2007.
(60) Provisional application No. 60/891,252, filed on Feb. 23, 2007.

(30) Foreign Application Priority Data
Feb. 23, 2007 (DE) 10 2007 009 412.6
Feb. 23, 2007 (DE) 10 2007 009 839.3

(51) Int. Cl. H01L 21/20; H01L 29/78; H01L 33/00

(52) U.S. Cl. 257/94; 438/479; 438/492; 257/192; 257/E33.013; 257/E29.068; 257/E21.04

(57) ABSTRACT

The present invention relates to a novel process for producing (Al, Ga)InN and AlGaInN single crystals by means of a modified HVPE process, and also to (Al, Ga)InN and AlGaInN bulk crystals of high quality, in particular homogeneity.

The III-V compound semiconductors produced by the process according to the invention are used in optoelectronics, in particular for blue, white and green LEDs and also for high-power, high-temperature and high-frequency field effect transistors.

The present invention relates to a novel process for producing (Al, Ga)InN and AlGaInN single crystals by means of a modified HVPE process. Here, AlGaInN is the abbreviation for AlₓGa_{1-x-y}In_{y}N, where 0≦x,y≦1, and (Al, Ga)InN means AlInN or GaInN.

Gallium nitride (GaN) is a so-called III-V compound semiconductor with a large electronic band gap which is used in optoelectronics, in particular for blue, white and green LEDs and also for high-power, high-temperature and high-frequency field effect transistors.

One problem when growing III-N materials is the fact that native substrates are not available in sufficient quality and in sufficient numbers, so that at present sapphire or silicon carbide are usually used as substrates. This means that the crystal lattices of the substrate and of the layer do not match one another. Nevertheless, by means of clever process control, for example using an SiO₂ mask or suitable buffer layers, it is still possible to achieve the situation whereby a monocrystalline layer is produced, although this has a very large number of crystal defects.

The defects which occur in the group III nitrides when performing heteroepitaxy on non-native substrates, such as sapphire and SiC, are mainly dislocations which spread along the c-axis in the direction of growth. For this reason, the defect density is reduced only slowly in the case of homogeneous growth with an increasing layer thickness. However, if the surface is structured so that lateral growth perpendicular to the c-axis is possible, then the dislocations do not perpetuate and therefore the defect densities in the laterally grown regions are much lower. However, a dislocation density which is homogeneously low over the entire substrate is not achieved here.

An alternative to the latter is the use of III-N substrates with a low dislocation density. However, the customary processes for producing A(III)-B(V) single crystals (e.g. GaAs or InP), that is to say preparation from the melt, are not possible in the case of GaN. The reason for this is that the nitrogen in the material has an extremely high vapour pressure at the necessary growth temperatures. It would therefore have to be placed in a crystal growing apparatus, which does not readily allow economic operation.

When searching for economic production processes for GaN single crystal materials with few defects, the long-known process of hydride vapour phase epitaxy (HVPE) appears promising. In HVPE, the compound semiconductor materials are produced from the metallic sources of the group III elements and hydrogen compounds of the group V elements of the semiconductor crystal.

Here, hydrogen chloride (HCl) and gallium are reacted at a high temperature in the range from approx. 700-900° C. to form gallium chloride, the latter flows further and subsequently comes into contact with gaseous ammonia on the support material, which is also referred to as the substrate. Under controlled pressure and at high temperatures, this mixture reacts to form GaN. The latter is deposited on the substrate and grows to form a GaN layer. Typical growth rates which can be achieved with a good material quality are between 50 and 150 μm/h. Such an HVPE process is described for example in Motoki et al., Jpn. J. Appl. Phys., Part 2, 40(2B):L140, February 2001, and in Tomita et al., phys. stat. sol. (a), 194(2):563, December 2002.

However, it has not yet been possible to achieve the crystal quality and homogeneity known in respect of other III-V semiconductor crystals.

U.S. Pat. No. 6,440,823 (Vaudo et al.) discloses an HVPE process for producing GaN single crystals. Vaudo et al. describe an HVPE process for growing GaN at temperatures of at most 1010° C. and also a 2-step HVPE process for growing (Al,Ga,In)N, wherein the growth temperature in the first step is at most 1020° C. and in the next step may lie between 1020° C. and 1250° C. For growing (Al,Ga,In)N, a number of sequences of metal sources (metal=Al, Ga or In) are described, over which gaseous HCl is passed. This process is very complicated and requires a lot of space in the corresponding apparatus, which results in considerable economic disadvantages.

Furthermore, Yu et al. (Journal of Ceramic Processing Research, Vol. 7, No. 2, pages 180-182 (2006)) describe an HVPE process for producing GaN layers using indium metal. Here, too, the indium is placed in a separate crucible, which entails a considerable continuous optimization effort when carrying out the process. Moreover, indium atoms are incorporated in the single crystal and it is only possible to obtain In-doped GaN crystals, which have an In content of 5×10¹⁶ at/cm³ and which are in need of improvement in terms of their crystal quality.

There is therefore a need to provide more efficient processes which can be used to produce (Al, Ga)InN and AlGaInN single crystals economically and in high yields.

It has now surprisingly been found on the one hand that (Al, Ga)InN and AlGaInN single crystals can be obtained in high yields by means of a modified HVPE process and on the other hand that higher growth rates and a very good crystal quality, in particular homogeneity, can be observed, so that more economic production is possible.

The subject matter of the present invention is therefore an HVPE process comprising the following steps:
a) providing a mixture consisting of (Al, Ga) and In metals,
b) reacting the metals according to a) with hydrogen compounds of the halogens at temperatures in the range from 500° C. to 950° C. to form the (Al, Ga)/In halides,
c) adding hydrogen compounds of the elements of main group V of the Periodic Table,
d) reacting the (Al, Ga)In halides formed according to b) with the hydrogen compounds according to c) on a substrate at temperatures in the range from 850° C. to 1200° C. to form (Al, Ga)N, and depositing it on the substrate,
e) removing the excess starting materials and also the gaseous byproducts that have formed.

For the case of growing AlGaInN, it is possible to use a second source comprising liquid Al or a mixture consisting of liquid Al and liquid In.

Suitable HVPE reactors in which the process according to the invention can be carried out are available for example from the company Aixtron. These are so-called horizontal hot wall reactors made of quartz, which are located in a multizone furnace.

One advantage of the process according to the invention is the fact that it is possible to use existing devices and no complicated new constructions are necessary. This means a much more economic process for producing (Al, Ga)InN and AlGaInN single crystals by means of HVPE.

The metals provided in step a) are (Al, Ga) and In metals of high purity. The purity is at least 99.999% by weight. The ratio In(I)/Ga(I) and/or Al(I) is selected in such a way that the In content in the (Al, Ga)InN and AlGaInN single crystal obtained is from 0 to 10 at. %, preferably between 1 and 5 at. %.

In one preferred variant of the process according to the invention, the molar ratio In(I)/Ga(I) and/or Al(I) on the source is up to 5×10⁻¹, preferably up to 3×10⁻¹, in particular up to 1×10⁻¹.

The mixture consisting of Al and/or Ga and In together is placed in a crucible. To this end, the metals are mixed beforehand and largely homogenized. In one variant of the process, Ga and/or Al and In are mixed in the melt. In this variant, In is melted and Ga and/or Al is added thereto. The Ga and/or Al may be added also as a melt, or else the metal is added to the In melt. By providing the gallium and/or aluminium and the indium together, conditions for the HVPE process are created which do not require constant readjustment during the process. In addition, the partial vapour pressures of the halides that are formed are optimized with respect to one another, so that more uniform transport is made possible.

The loaded crucible is then placed into the HVPE apparatus and the device is closed. The apparatus is then evacuated a number of times and filled with inert gas. Prior to heating, an atmosphere of inert gas/hydrogen is set. The temperature in the crucible area is then increased to 500° C. to 950° C. and the hydrogen compounds of the halogens are added.

The hydrogen compounds of the halogens are usually added in a stream of protective gas. The content of hydrogen compounds of the halogens in the protective gas stream is set via the flow rates. This is up to 500 sccm of hydrogen compounds of the halogens. However, depending on the dimensions of the HVPE apparatus, higher flow rates are also possible.

The total pressure in the area is from atmospheric pressure up to approximately 50 mbar, preferably in the range from 50 to 1000 mbar, in particular in the range from 700 to 1000 mbar.

The ratio of elements of group V to III is ≧1, preferably in the range from 1 to 100, in particular in the range from 10 to 40.

The hydrogen compounds of the halogens are preferably gaseous hydrogen halides, in particular HCl, HBr, HF and/or HI, particularly preferably HCl.

The reaction of the metals with hydrogen compounds of the halogens in step b) takes place at temperatures in the range from 500° C. to 950° C., preferably in the range from 800° C. to 900° C.

The addition of the hydrogen compounds of the elements of main group V of the Periodic Table in step c) takes place by supplying them in a stream of protective gas. The content of hydrogen compounds in the protective gas stream results from the abovementioned ratio of the elements of group V to III.

The hydrogen compounds are preferably gaseous compounds or those which have a sufficient partial vapour pressure under HVPE conditions. Suitable hydrogen compounds are saturated, acyclic azanes of the composition NₙHₙ₊₂, in particular ammonia (NH₃), and also unsaturated, acyclic azenes of the composition NₙHₙ and other NH compounds which are not explicitly mentioned and which break down to release ammonia.

All suitable materials are used as substrate. Suitable substrates are sapphire, silicon, silicon carbides, diamond, lithium gallates, lithium aluminates, zinc oxides, spinels, magnesium oxides, ScAlMgO₄, GaAs, GaN, AlN and also the substrates mentioned in U.S. Pat. No. 5,563,428. Preference is given to sapphire, SiC, GaN, Si and GaAs.

The reaction of the Al and/or Ga/In halides formed according to b) with the hydrogen compounds according to c) takes place at temperatures in the range from 850° C. to 1200° C., preferably in the range from 1020° C. to 1070° C. The formation and deposition of the single crystal takes place directly on the substrate.

The byproducts produced during the formation of the (Al, Ga)InN and AlGaInN, such as HCl for example, are removed with the carrier gas stream. The same applies in respect of unreacted reagents.

Nitrogen and hydrogen are used as carrier gases, wherein the hydrogen concentration may lie in the range from 0 to 100% by volume, more preferably between 30 and 70% by volume.

Using the process according to the invention, growth rates of 20 μm/h to 1 mm/h, preferably 150 to 300 μm/h, are detected for (Al, Ga)InN and AlGaInN mixed crystals, so that said process is suitable for commercial production.

Using the process according to the invention, it is possible to produce (Al, Ga)InN and AlGaInN single crystals of high quality, in particular high homogeneity.

Another subject matter of the present invention are therefore (Al, Ga)InN and AlGaInN bulk crystals, wherein, when surface mapping is carried out, the standard deviation of the determined indium concentration is 5% or less, preferably 1% or less.

The measurement of the In homogeneity, that is to say the fluctuation of the indium concentration, takes place by means of X-ray diffraction, e.g. as the spatial distribution of the absolute positions of X-ray diffraction curves corresponding to the diffraction at certain network planes. To this end, so-called rocking curve mappings (recording of ω-scans at various points on the surface) can be carried out. In the case of growth in the [0001] direction, it is possible to use e.g. the reflection of the (0002) network planes in the ω-scans.

The standard deviation can be determined by carrying out rocking curve mapping measurements at a large number, e.g. 100, measurement points on the surface (i) or (ii) to be measured, forming the mean of the half-widths of all the measurements, and determining the standard deviation with respect to this mean via a customary statistical evaluation.

In the present case, the rocking curve mappings are carried out using a commercial high-resolution X-ray diffractometer, which operates with Cu Kα1 radiation and with a collimating lens on the input side. The diffractometer is optimized in such a way that the device component on the spread of the rocking curves is less than 50%. The step width in ω is selected in such a way that at least 10 measurement points are located in the half-width. When measuring on the sample surface, the (0002) reflex is used and the step width in the x and y direction is ≦5 mm. The lateral dimensions of the X-ray focus are ≦5 mm on the surface. The edge exclusion zone is at most 3 mm from the wafer edge.

The (Al, Ga)InN and AlGaInN crystals according to the invention have an In content of up to 10 at. %, preferably between 1 and 5 at. %.

The single crystals obtained have a defect density of less than 1×10⁷, preferably less than 1×10⁶ defects per cm².

The III-V compound semiconductors produced by the process according to the invention are used in optoelectronics, in particular for blue, white and green LEDs and also for high-power, high-temperature and high-frequency field effect transistors, so that components for optoelectronics also form the subject matter of the invention.

1. A hydrogen vapor phase epitaxy (“HVPE”) process for producing (Al, Ga)InN and AlGaInN single crystals, comprising the following steps:
a) providing a mixture consisting of (Al, Ga) and In metals,
b) reacting the metals according to a) with hydrogen compounds of the halogens at temperatures in the range from 500° C. to 950° C. to form the (Al, Ga)/In halides,
c) adding hydrogen compounds of the elements of main group V of the Periodic Table,
d) reacting the (Al, Ga)In halides formed according to b) with the hydrogen compounds according to c) on a substrate at temperatures in the range from 850° C. to 1200° C. to form (Al, Ga)N, and depositing it on the substrate,
e) removing the excess starting materials and also the gaseous byproducts that have formed.

2. The process according to claim 1, wherein the aluminium is placed in a separate crucible.

3. The process according to claim 1 wherein the molar ratio In(I)/Ga(I) and/or Al(I) on the source is up to 5×10⁻¹.

4. The process according to claim 1, wherein the mixture consisting of Al and/or Ga and In together is placed in a crucible.

5. The process according to claim 1, wherein the metals used in step a) have been mixed beforehand and largely homogenized.

6. The process according to claim 1, wherein the metals used in step a) are mixed beforehand in the melt.

7. The process according to claim 1, wherein the reaction in step b) takes place at temperatures in the range from 800° C. to 900° C.

8. The process according to claim 1, wherein said substrate is sapphire, silicon, silicon carbides, diamond, lithium gallates, lithium aluminates, zinc oxides, spinels, magnesium oxides, ScAlMgO₄, GaAs, GaN or AlN.

9. The process according to claim 1, wherein the reaction in step c) takes place at temperatures in the range from 1020° C. to 1070° C.

10. (Al, Ga)InN and AlGaInN single crystals having an In content of up to 10 atomic %, obtainable by a process comprising the following steps:
a) providing a mixture consisting of (Al, Ga) and In metals,
b) reacting the metals according to a) with hydrogen compounds of the halogens at temperatures in the range from 500° C. to 950° C. to form the (Al, Ga)/In halides,
c) adding hydrogen compounds of the elements of main group V of the Periodic Table,
d) reacting the (Al, Ga)In halides formed according to b) with the hydrogen compounds according to c) on a substrate at temperatures in the range from 850° C. to 1200° C. to form (Al, Ga)N, and depositing it on the substrate,
e) removing the excess starting materials and also the gaseous byproducts that have formed.

11. (Al, Ga)InN and AlGaInN single crystals having an in content of up to 10 atomic %, in which, when surface mapping is carried out, the standard deviation of the determined indium concentration is 5% or less.

12. The (Al, Ga)InN and AlGaInN single crystals according to claim 11, wherein the standard deviation of the determined indium concentration is 1% or less.

13. (canceled)

14. A component for optoelectronics which comprises the (Al, Ga)InN or AlGaInN single crystals according to claim 10.

15. The process according to claim 2 wherein the molar ratio In(I)/Ga(I) and/or Al(I) on the source is up to 3×10⁻¹.

16. The process according to claim 2 wherein the molar ratio In(I)/Ga(I) and/or Al(I) on the source is up to 1×10⁻¹.

17. A blue, white and green LED, a laser diode or a high-power, high-temperature and high-frequency field effect transistor which comprises the (Al, Ga)InN or AlGaInN single crystals according to claim 10.
